(19) United States
(12) Patent Application Publication
(10) Pub. No.: US 2008/0296780 A1
(43) Pub. Date: Dec. 4, 2008

(54) MEMORY DEVICES INCLUDING SEPARATING INSULATING STRUCTURES ON WIRES AND METHODS OF FORMING

(75) Inventor: Cheol-joon Yoo, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/105,117

(22) Filed: Apr. 17, 2008

(30) Foreign Application Priority Data
Jun. 4, 2007 (KR) 10-2007-0054639

(51) Int. Cl. H01L 23/49; H01B 13/18

(52) U.S. Cl. 257/780; 156/51; 257/E23.025

(57) ABSTRACT

Wires included in integrated circuit devices can have separate insulating structures formed thereon. The separate insulating structures on the wires can surround respective cross sectional portions of the wires, which can function as “stand-offs” to prevent immediately neighboring wires (or other neighboring components) from shorting together to thereby allow a reduction in defects associated with devices having reduced pitch between the wires (or other components).

### CROSS-REFERENCE TO RELATED APPLICATIONS

The present application claims priority to Korean Patent Application No. 2007-0054639, filed in the Korean Intellectual Property Office on Jun. 4, 2007, the disclosure of which is incorporated herein by reference.

### FIELD OF THE INVENTION

The present invention relates to the field of semiconductors in general, and more particularly, to semiconductor wiring and related methods.

### BACKGROUND

As circuits have become more highly integrated, the spacing (i.e., pitch) between wires used to conduct signals between a chip and a substrate (on which the chip is mounted) has been reduced. The signals can be provided to/from outside the device package which houses the integrated circuit chip along with the substrate.

As part of the packaging process, the substrate (having a chip mounted thereon and the wires connecting the two) can be subjected to a molding process which is used to encapsulate the integrated circuit and substrate in a device package. Because the pitch between wires can be small, the molding process can cause some of the wires to touch one another (or the substrate) which can create an electrical short. This phenomenon is sometimes referred to as “wire sweeping.”

One of the ways in which wire sweeping is addressed is to coat the wires with a dielectric material during fabrication of the integrated circuit device. The coating of wires is described in, for example, JP 2004-282021 and in U.S. Pat. No. 6,822,340.

### SUMMARY

Embodiments according to the invention can provide semiconductor devices including separating insulating structures on wires and methods of forming. Pursuant to these embodiments, wires included in integrated circuit devices can have separate insulating structures formed thereon. The separate insulating structures on the wires can surround respective cross sectional portions of the wires, which can function as “stand-offs” to prevent immediately neighboring wires (or other neighboring components) from shorting together to thereby allow a reduction in defects associated with devices having reduced pitch between the wires (or other components). In some embodiments according to the invention, the separate insulating structures can have a substantially spherical external shape. In other embodiments according to the invention, the separate insulating structures can have a substantially oval external shape. In still further embodiments according to the invention, the spacing between the separate insulating structures can be substantially equal, and further, the exposed portions of the wire located between the separate insulating structures can also be substantially equal.

### BRIEF DESCRIPTION OF THE DRAWINGS

FIG. 1 is a cross sectional schematic representation of an integrated circuit device including a chip mounted on a substrate electrically connected to one another by wires having separate insulating structures formed thereon in some embodiments according to the invention.

FIG. 2 is a cross sectional schematic representation of an integrated circuit device including two different-sized chips stacked on an integrated circuit substrate and electrically connected to the substrate by wires having separate insulating structures formed thereon in some embodiments according to the invention.

FIG. 3 is a cross sectional schematic representation of an integrated circuit device including same-sized chips stacked on an integrated circuit substrate and electrically connected to the substrate by wires having separate insulating structure formed thereon in some embodiments according to the invention.

FIG. 4 is a cross sectional schematic illustration of an integrated circuit device including two same-sized chips stacked on an integrated circuit substrate and electrically coupled to the substrate by wires having separate insulating structures formed thereon in some embodiments according to the invention.

FIG. 5 is a cross sectional schematic representation of an integrated circuit device including two same-sized chips stacked on an integrated circuit substrate and electrically connected to the substrate by wires having separate insulating structures thereon in some embodiments according to the invention.

FIG. 6 is a photograph of wires electrically connecting a chip to an integrated circuit substrate having separate insulating structures formed thereon in some embodiments according to the invention.

FIG. 7 is a close-up view of the wires shown in FIG. 6 illustrating the separate insulating structures in greater detail in some embodiments according to the invention.

FIG. 8 is a schematic representation of an insulating structure having a substantially spherical cross section in some embodiments according to the invention.

FIG. 9 is schematic representation of a separate insulating structure having a substantially oval cross section in some embodiments according to the invention.

FIGS. 10A and 10B are cross sectional views of spherical and oval shaped cross sections of separate insulating structures having substantially annular shapes in some embodiments according to the invention.

FIG. 11 is a schematic representation of a number of groups of wires where each wire in a particular group is narrowly spaced from one another compared to the spacing between the groups and having separate insulating structures formed on the wires in the group in some embodiments according to the invention.

FIG. 12 is a schematic representation of wires being substantially equally spaced from one another and having a single separate insulating structure that surrounds cross sectional portions of each of the wires in some embodiments according to the invention.

FIG. 13 is a schematic representation of wires having separate insulating structures formed thereon so that the separate insulating structures formed on immediately neighboring ones of the wires form a zigzag pattern in some embodiments according to the invention.

FIG. 14 is a schematic representation of a memory card incorporating memory devices with wires therein having separate insulating structures formed thereon in some embodiments according to the invention.

FIG. 15 is a schematic representation of an electronic system including memory devices with wires formed therein having separate insulating structures formed thereon in some embodiments according to the invention.

FIGS. 16-18 are cross sectional schematic illustrations of methods of forming separate insulating structures on wires included therein in some embodiments according to the invention.

FIG. 19 is a table that shows exemplary values associated with an insulating material that can be used to provide the separate insulating structures in some embodiments according to the invention.

FIG. 20 is a photograph of wires having separate insulating structures formed thereon in some embodiments according to the invention.

FIG. 21 is a more detailed view of FIG. 20 with wires having separate insulating structures formed thereon in some embodiments according to the invention.

FIGS. 22 and 23 are photographs of cross sections of wires in an integrated circuit device having separate insulating structures formed thereon in some embodiments according to the invention.

FIG. 23 is a photograph showing external shapes of separate insulating structures in some embodiments according to the invention.

FIG. 24 is a photograph showing external shapes of separate insulating structures in some embodiments according to the invention.

### DESCRIPTION OF EMBODIMENTS ACCORDING TO THE INVENTION

The present invention is described more fully hereinafter with reference to the accompanying drawings, in which embodiments of the invention are shown by way of example. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. Moreover, each embodiment described and illustrated herein includes its complementary conductivity type embodiment as well.

It will be understood that when an element is referred to as being “connected to,” “coupled to” or “responsive to” (and/or variants thereof) another element, it can be directly connected, coupled or responsive to the other element or intervening elements may be present. In contrast, when an element is referred to as being “directly connected to,” “directly coupled to” or “directly responsive to” (and/or variants thereof) another element, there are no intervening elements present. Like numbers refer to like elements throughout. As used herein, the term “and/or” includes any and all combinations of one or more of the associated listed items and may be abbreviated as “/”.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising” (and/or variants thereof), when used in this specification, specify the presence of stated features, integers, steps, operations, elements, and/or components, but do not preclude the presence or addition of one or more other features, integers, steps, operations, elements, components, and/or groups thereof. In contrast, the term “consisting of” (and/or variants thereof) when used in this specification, specifies the stated number of features, integers, steps, operations, elements, and/or components, and precludes additional features, integers, steps, operations, elements, and/or components.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and the present application, and will not be interpreted in an idealized or overly formal sense unless expressly so defined herein.

As described herein in greater detail, in some embodiments according to the invention, wires included in integrated circuit devices can have separate insulating structures formed thereon. The separate insulating structures on the wires can surround respective cross sectional portions of the wires, which can function as “stand-offs” to prevent immediately neighboring wires (or other neighboring components) from shorting together to thereby allow a reduction in defects associated with devices having reduced pitch between the wires (or other components). In some embodiments according to the invention, the separate insulating structures can have a substantially spherical external shape. In other embodiments according to the invention, the separate insulating structures can have a substantially oval external shape. In still further embodiments according to the invention, the spacing between the separate insulating structures can be substantially equal, and further, the exposed portions of the wire located between the separate insulating structures can also be substantially equal.

In still further embodiments according to the invention, the separate insulating structures can be formed on wires that are immediately neighboring in a lateral direction and/or immediately neighboring in a vertical direction. For example, in some integrated circuit devices, multiple chips are stacked on a substrate so that there is a potential for shorting between wires in both the vertical direction (i.e., electrical shorts between wires that are coupled to an upper or lower chip) as well as electrical shorting in the lateral direction between wires that are connected to the same chip.

In still further embodiments according to the invention, the separate insulating structures can help avoid electrical shorts between the wire and the chip or substrate itself. For example, in one process sometimes referred to as a “bump reverse process,” the wires are first bonded to the substrate and are then bonded to the chips. This process can reduce the spacing between the wire and the surface of the chip because of the order in which the wires are bonded and/or the reduced height which the wires are laterally bonded the chip. Accordingly, in some embodiments according to the invention, the separate insulating structures can act as a stand-off between the wire and the surface of the chip and/or the substrate itself to reduce electrical shorts.

In still further embodiments according to the invention, the separate insulating structures can be formed by pretreating the wires to reduce the surface tension between the wire and the material that is to be deposited on the wire. Once the pretreatment is complete, the separate insulating structures can be formed to surround respective cross sectional portions of the wire. In some embodiments according to the invention, the pretreating process can include applying a plasma treatment using Argon or Nitrogen. In still other embodiments according to the invention, the pretreating can be provided using a wet process.

In still further embodiments according to the invention, the separate insulating structures can be provided by applying an insulating liquid to the wire including a polymer with a resin base, an adhesive strength reinforcing agent, an indurative catalyst, and a solvent. In some embodiments according to the invention, the base resin can be a polyimide resin, an acrylic resin, an epoxy resin, or a silicone resin. In some embodiments according to the invention, the solvent can be an organic solvent that comprises less than about 50% by weight of the polymer.

In still further embodiments according to the invention, the formation of the separate insulating structures can be followed by an induration treatment including the heating of the separate insulating structures at a temperature of about 200° C. In still further embodiments according to the invention, the formation of the separate insulating structures can be followed by an induration treatment using ultraviolet radiation.

In still further embodiments according to the invention, the formation of the separate insulating structures can be followed by two separate induration treatments where a first induration treatment volatizes a solvent used to form the plurality of separate insulating structures. A second induration treatment can be provided after the first induration treatment, which can include providing an epoxy molding compound that is used to form a molding material applied over the separate insulating structures. In some embodiments according to the invention, the first induration treatment described above can be provided at a temperature greater than about 70° C.

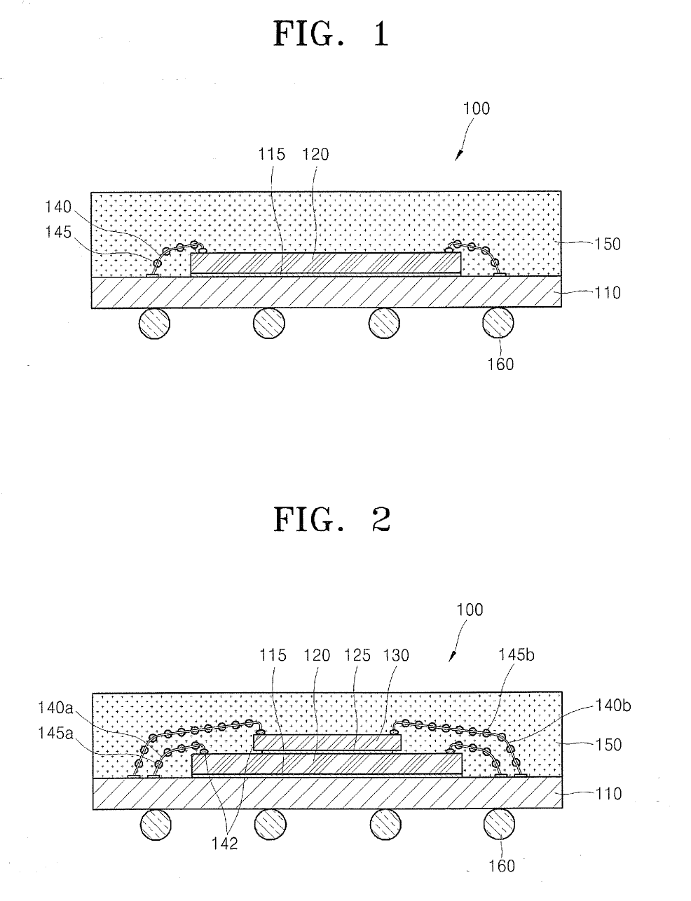

FIG. 1 is a cross sectional schematic representation of an integrated circuit device 100 including an integrated circuit chip 120 (referred to hereinafter as “chip”) mounted on a substrate 110. In particular, the chip 120 is mounted to the substrate 110 by an adhesive 115. Electrical signals are conducted to/from the chip 120 by a plurality of wires 140 that electrically couple the chip 120 to the substrate 110. Although not explicitly shown, the wires 140 can be coupled to bonding pads (or the like) on the substrate 110 and/or the chip 120.

The integrated circuit device is encapsulated by a molding material 150 that can fix the structures therein and provide structural support for the integrated circuit device 100. The integrated circuit device 100 can also include solder bumps 160 attached to an opposing side of the substrate 110 relative to the chip 120. The solder bumps 160 can allow the integrated circuit device 100 to be mounted to other structures which may also, in turn, be further packaged for later use. It will be understood that the solder bumps 160 are not essential elements as, for example, some electronic devices, such as memory cards or the like, can have plate type terminals for coupling the chip 120 to a host system.

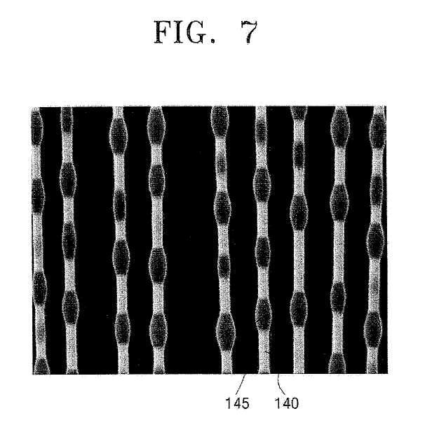

A plurality of separate insulating structures 145 can be formed on the wires 140 to surround respective cross sectional portions thereof. Portions of the wire located between the plurality of separate insulating structures 145 can be free of the separate insulating structures (sometimes referred to herein as “exposed”). As shown in FIGS. 6 and 7, the separate insulating structures 145 on the wires can act as spacers or standoffs to reduce the likelihood of shorting between immediately neighboring ones of the wires 140. More particularly, the separate insulating structures 145 formed on the immediately neighboring wires 140 can act as stand-offs so that if (due to, for example, the thinness of the wires) the molding process used to package the integrated circuit 100 causes some of the wires 140 to deflect and touch immediately neighboring wires, the separate insulating structures 145 can function as insulating stand-off structures to prevent electrical shorting between the immediately neighboring wires, thereby allowing an improvement in the reliability of highly integrated circuits 100 and particularly in highly integrated circuits having closely-spaced wires and/or very thin wires.

FIG. 2 is a cross sectional schematic representation of an integrated circuit device 100 including a first chip 120 and a second chip 130 stacked thereon where the second chip 130 is smaller than the first chip 120. As further shown in FIG. 2, the first and second chips 120 and 130 are coupled to one another by an adhesive layer 125. A first set of wires 140A electrically connects the first chip 120 to the substrate 110. A second set of wires 140B electrically connects the second chip 130 to the substrate 110. A plurality of first separate insulation structures 145A is on the first set of wires 140A to surround cross sectional portions thereof. A plurality of second separate insulation structures 145B is on the second set of wires 140B to surround cross sectional portions thereof.

Accordingly, the first and second wires 140A and 140B immediately neighbor one another in a vertical direction so that the formation of the molding material 150 may cause the immediately neighboring wires to deflect which may cause an electrical short but for the formation of the separate insulating structures 145A and 145B formed respectively on the first and second wires 140A and 140B. Furthermore, the first and second wires 140A and 140B can be formed according to what is referred to as a “bump-forward” bonding process where the wire is first bonded to the chip 120 or 130 and then is bonded to the substrate 110. Accordingly, the separate insulating structures 145A/145B formed on the first and second wires 140A/140B can prevent electrical shorting between immediately neighboring wires (including both laterally immediately neighboring wires and vertically immediately neighboring wires). Furthermore, the separate insulating structures 145A/145B can also reduce the likelihood that the wires may short against surfaces of the first and second chips 120 and 130.

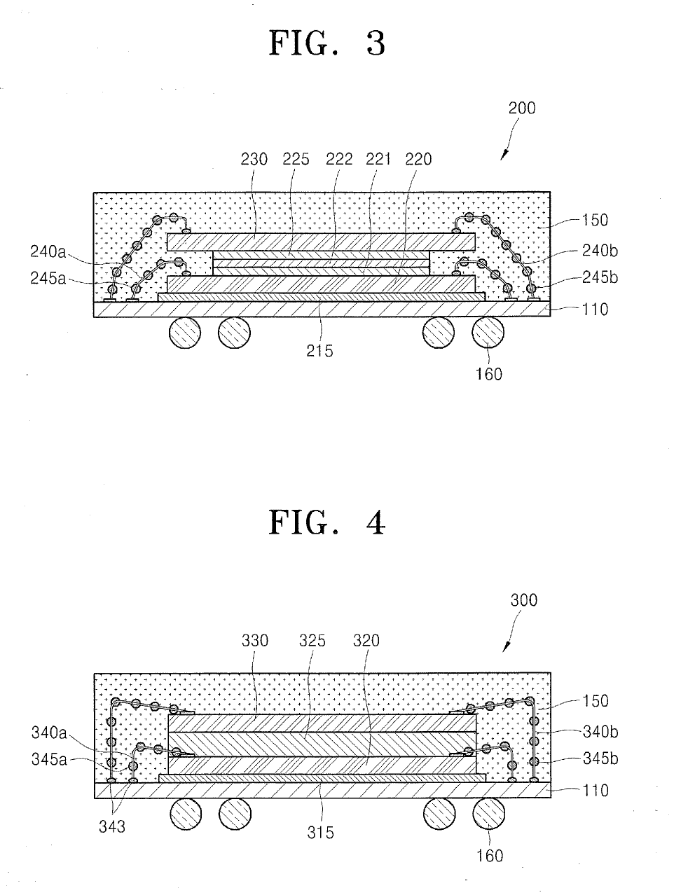

FIG. 3 is a cross sectional schematic representation of an integrated circuit device 200 including first and second chips 220 and 230, respectively formed on the substrate 110 where the first and second chips 220 and 230 are approximately identical in size. As further shown in FIG. 3, a first set of wires 240A electrically connects the first chip 220 to the substrate 110 whereas a second set of wires 240B electrically connects the second chip 230 to the substrate 110. According to FIG. 3, the first and second wires 240A/240B include respective pluralities of separate insulating structures 245A/245B formed thereon to reduce the likelihood of electrical shorting between immediately neighboring (vertically and/or laterally) wires by acting as stand-offs between those wires. As further shown in FIG. 3, the first and second chips 220 and 230 are separated by an interposing layer 221 which can act as a vertical stand-off to separate the first and second chips to allow the respective wires that electrically couple the chips to the substrate 110 adequate space for bonding to the respective pads of the chips 220 and 230. Furthermore, the bonding process depicted in FIG. 3 can also be provided by a bump-forward process as described above in reference to FIG. 2.

FIG. 4 is a cross sectional schematic representation of an integrated circuit device 300 including a first chip 320 and a second chip 330 stacked on the substrate 110 and separated by an adhesive layer 325. As further shown in FIG. 4, the first chip 320 is electrically connected to the substrate 110 by a first set of wires 340A having a plurality of separate insulating structures 345A formed thereon. A second set of wires 340B electrically connects the second chip 330 to the substrate 110. The second set of wires 340B has a respective plurality of separate insulating structures 345B formed thereon which can reduce the likelihood of electrical shorting between immediately neighboring wires (either vertically immediately neighboring or laterally immediately neighboring).

It will be understood that the separate insulating structures 345A/345B formed on the wires can also reduce the likelihood that the respective wire will electrically short to the respective surfaces of the chips at the outer edges thereof. In particular, the bonding approach depicted in FIG. 4 employs what is referred to as a “bump-reverse” bonding process in which a wire is first bonded to pads 343 on the substrate 110 and is then bonded to pads at the outer edges of the respective chip 320 or 330. It will be understood that this bump-reverse process can increase the likelihood that (without the inclusion of the separate insulating structures 345A/345B) the wires may short against the respective surfaces of the first and second chips 320 and 330.

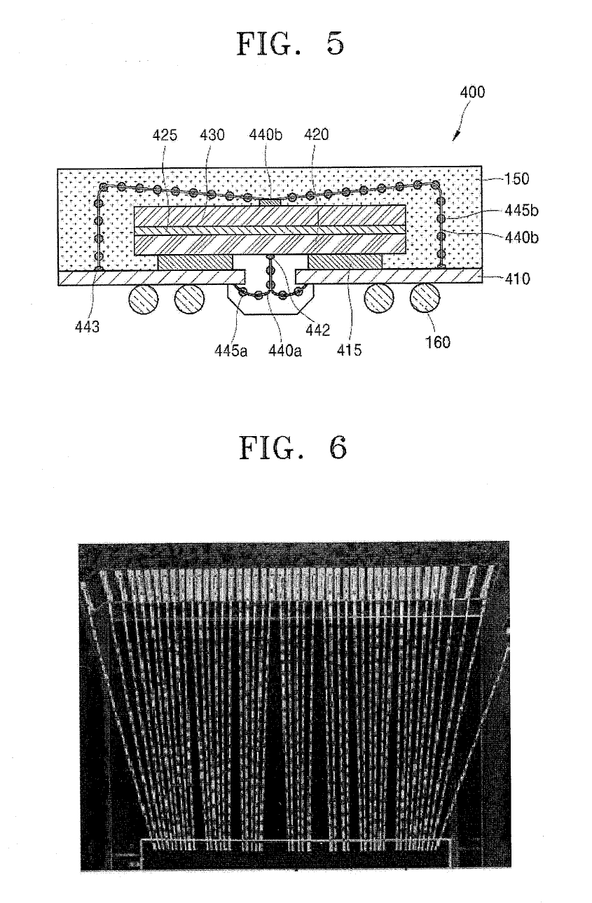

FIG. 5 is a cross sectional schematic representation of an integrated circuit device 400 including first and second chips 420 and 430 stacked on a substrate 410. As further shown in FIG. 5, a first set of wires 440A electrically couples the substrate 410 to a bonding pad 442 located on a lower surface of the first chip 420. As shown, the bonding pad 442 is located at a central portion of the lower surface of the first chip 420. Further, a second set of wires 440B electrically couples the substrate 410 to a centrally located bonding pad 440B located on an upper surface of the second chip 430.

As further shown in FIG. 5, the first and second wires 440A and 440B have respective pluralities of separate insulating structures 445A/445B formed thereon. As described herein, the separate insulating structures 445A/445B can surround respective cross sectional portions of the wires 440A/440B on which they are formed to act as stand-offs so that the wires are less likely to short against an immediately neighboring (vertically and/or laterally) wires or other surfaces. It will be understood that the bonding arrangement shown in FIG. 5 can also be formed according to the bump-reverse process described above in reference to FIG. 4. As described above in reference to FIGS. 6 and 7, the separate insulating structures 445 on the wires can act as spacers or standoffs to reduce the likelihood of shorting between immediately neighboring ones of the wires 440.

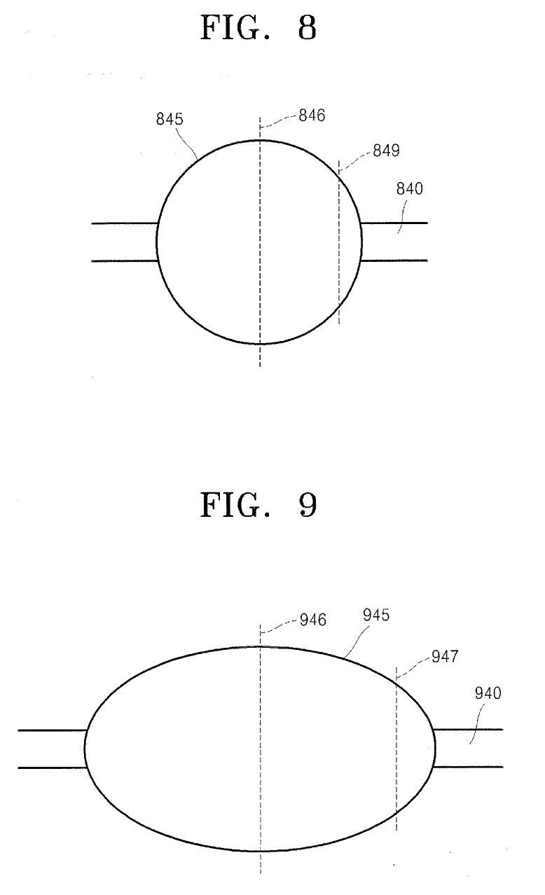

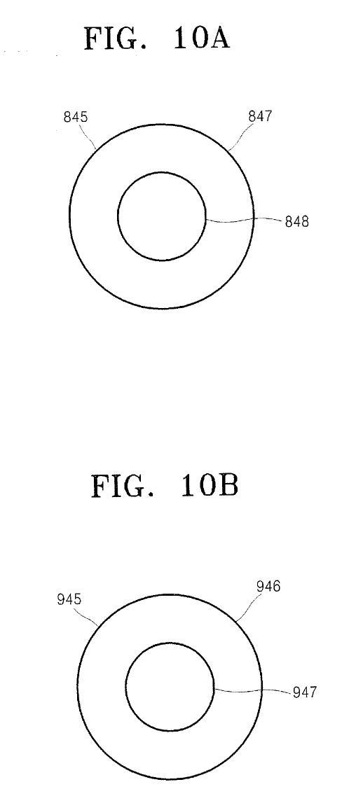

FIG. 8 is a schematic representation of a separate insulating structure 845 formed on a wire 840 to surround a respective cross sectional portion of the wire 840. In particular, an external shape of the separate insulating structure 845 can be a substantially spherical shape. Furthermore, a cross sectional view of the separate insulating structure 845 taken along the line 846 shows that the cross section has a substantially annular shape as illustrated in FIG. 10A. In particular, the external shape 847 and the inner shape 848 of the separate insulating structure 845 shown in FIG. 10A are substantially circular and coaxially formed. Furthermore, an interior region enclosed by the inner shape 848 is normally occupied by the wire 840 which the separate insulating structure 845 surrounds at a portion corresponding to the cross section 846. Furthermore, a cross section 849 located near an edge of the separate insulating structure 845 has a smaller diameter than the cross section taken at the central portion.

FIG. 9 is a schematic representation of a separate insulating structure 945 formed on a wire 940 wherein the separate insulating structure 945 has a substantially oval shape in some embodiments according to the invention. In particular, the oval shape of the separate insulating structure 945 formed on the wire 940 surrounds a respective cross sectional portion of the wire 940 to provide a substantially oval annular shape as shown in FIG. 9, Furthermore, as shown in FIG. 10B, a cross section of the oval annular shaped separate insulating structure 945 taken at a central portion 946 thereof is larger than a cross sectional diameter of the oval separate insulating structure 945 taken near an edge portion 947.

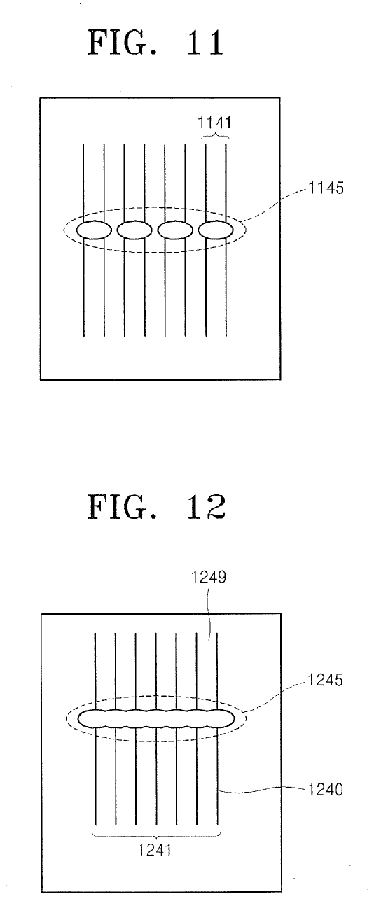

FIG. 11 is a schematic representation of a plurality of closely spaced wires 1141 being more widely spaced from immediately neighboring pluralities of wires and having a plurality of separate insulating structures 1145 formed thereon in some embodiments according to the invention. It will be understood that although only a single separate insulating structure 1145 is shown formed on closely spaced wires 1141, in some embodiments according to the invention, additional insulating structures can be formed.

According to FIG. 11, the closely spaced wires 1141 are spaced close enough to one another so that the separate insulating structures 1145 are formed together on the closely spaced wires 1141. Furthermore, a group of the closely spaced wires 1141 define a group of wires that is more widely spaced apart from an immediately neighboring group of closely spaced wires 1141. Accordingly, the separate insulating structure 1145 formed on an immediately neighboring closely spaced set of wires 1141 is separate from the other separate insulating structures 1145. Accordingly, the separate insulating structure 1145 shown in FIG. 11 surrounds respective cross sectional portions of all the wires included in one of the groups of closely spaced wires 1141. Furthermore, immediately neighboring closely spaced wires have formed thereon respective separate insulating structures 1145 which can act as insulating stand-offs against the immediately neighboring groups of closely spaced wires 1141.

FIG. 12 is a schematic representation of a group of wires 1241 having substantially equal spacing 1249 therebetween. Each of wires 1240 included in the group 1241 has formed thereon a separate insulating structure 1245 which surrounds respective cross sectional portions of each of the wires including the group 1241. Accordingly, the spacing 1249 between the wires 1240 and the group 1241 is selected to allow the formation of the separate insulating structure 1245 to surround each of the respective cross sectional portions of each of the wires in the group 1241.

FIG. 13 is a schematic representation of wires 1341 having respective separate insulating structures 1345 formed thereon to surround respective cross sectional portions of each of the wires 1341. Furthermore, separate insulating structures 1345 formed on immediately neighboring ones of the wires 1341 are offset from one another to define a zigzag pattern across the wires as illustrated by lines 1343 and 1344.

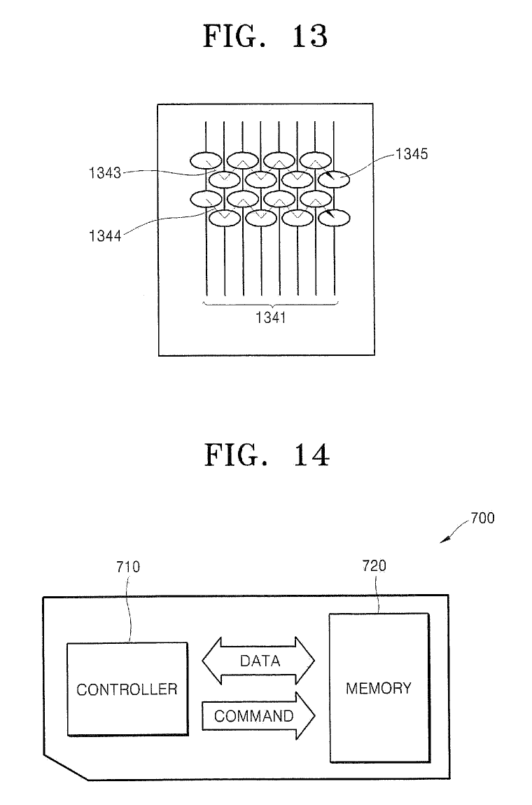

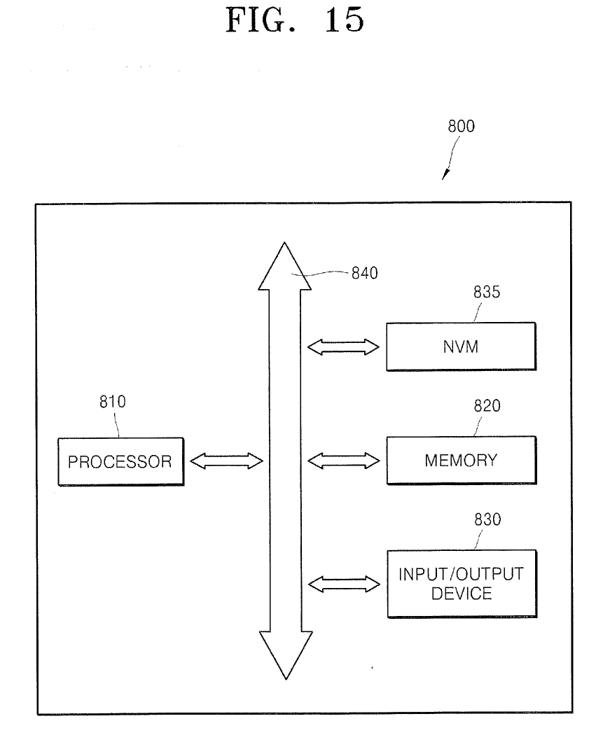

FIG. 14 is a schematic representation of a memory card 700 including memory devices having wires therein with separate insulating structures formed thereon in some embodiments according to the invention. According to FIG. 14, a nonvolatile memory controller 710 can coordinate overall operations of the memory card 700 including operations of a memory 720 that is configured to store and retrieve data in response to commands from the controller 710. Furthermore, the memory 720 includes memory devices packaged as described herein and including wires with separate insulating structures formed thereon in some embodiments according to the invention and as described herein.

The memory card 700 illustrated in FIG. 14 conforms to a “form-factor” (i.e., physical size and shape of the memory card) to provide a Multi-Media Card (MMC), Secure Digital memory card, Memory Stick etc. that has a size and shape that allows such memory cards to be used with other compliant devices, such as readers. As known to those skilled in the art, SD represents a later developed version of the MMC standard, which may allow MMC compliant memory cards to be used with SD compliant devices. In some embodiments according to the invention, MMC/SD form-factor compliant devices measure about 32 mm×about 24 mm×about 1.4 mm. The MMC and SD standards are discussed further on the world-wide-web at “www.mmca.org.”

FIG. 15 is a schematic representation of an electronic system 800 including a processor circuit 810 that is configured to coordinate overall operation of the electronic system 800 via a bus 840 that is coupled to a volatile memory system 820, an input/output system interface 830, and a nonvolatile memory system 835. The memory system 820 and the nonvolatile memory system 835 can include memory devices packaged as described herein and including wires having separate insulating structures formed thereon in some embodiments according to the invention and as described herein.

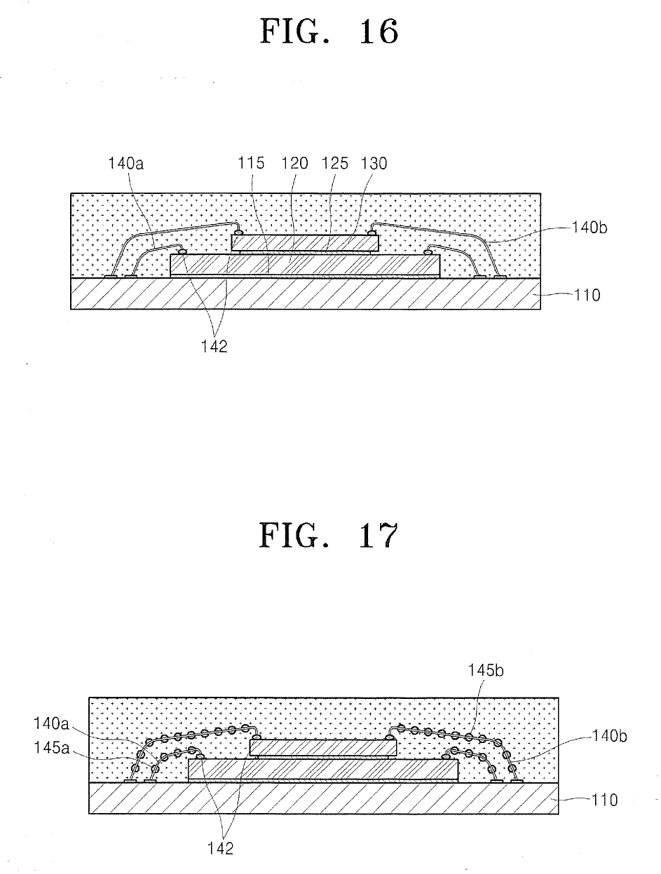

FIGS. 16-18 are cross sectional schematic illustrations of methods of forming separate insulating structures on wires in integrated circuit devices in some embodiments according to the invention. According to FIG. 16, first and second chips 120 and 130 are mounted on a substrate 110. The first chip 120 is fixed to the substrate 110 by an adhesive layer 115 and the second chip 130 is fixed to the first chip 120 by a second adhesive layer 125. As shown in FIG. 16, the first chip 120 is larger than the second chip 130. As further shown in FIG. 16, a first set of wires 140A electrically connects the first chip 120 to bonding pads on the substrate 110. A second set of wires 140B electrically connects the second chip 130 to a second set of bonding pads on the substrate 110. It will be understood that the structure shown in FIG. 16 can be provided according to any known process.

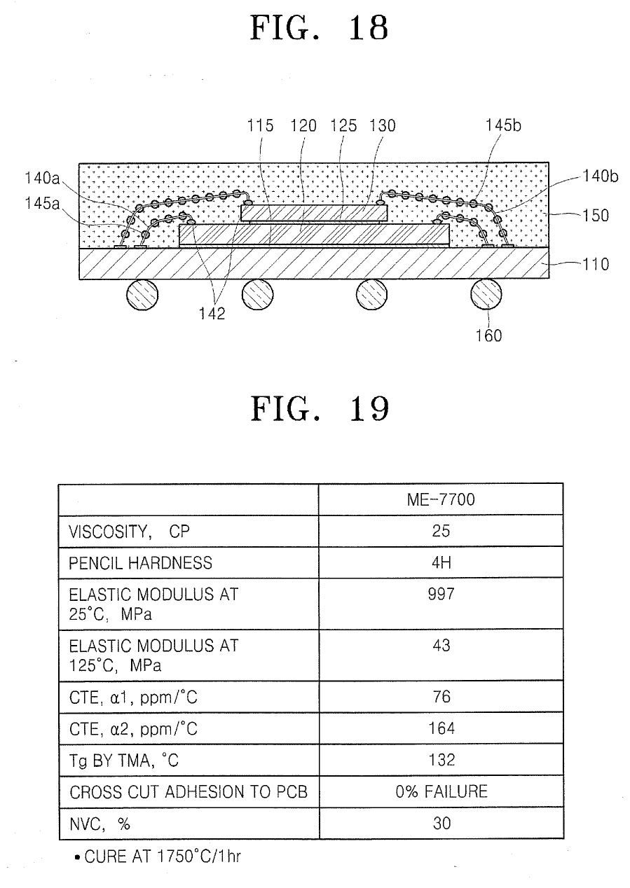

According to FIG. 17, a pretreatment process is provided to “wet” the surfaces of the wires 140A and 140B to prepare for receiving the insulating material used to form the separate insulating structures in some embodiments according to the invention. For example, in some embodiments according to the invention, the pretreatment process can be provided by a plasma treatment using Argon or Nitrogen as an ambient environment. In other embodiments according to the invention, the pretreatment process can be provided by a wet treatment. It will be understood that the pretreatment process can cause a reduction in the surface tension between the respective wires and the insulating material that is to be deposited on the wire. Reducing the surface tension between the wire and the material can promote the formation of the separate insulating structures at more regular intervals on the wires and to have a more regular shape (e.g., oval, spherical, etc.).

After the pretreatment process, the separate insulating structures can be formed by distributing a liquid of insulating material over the integrated circuit for deposition on the wires 140A and 140B. In particular, in some embodiments according to the invention, the insulating liquid applied to the wires can include a polymer with a resin base, an adhesive strength reinforcing agent, an indurative catalyst, and a solvent. In some embodiments according to the invention, the base resin described above can include a polyimide resin, an acrylic resin, an epoxy resin and/or a silicone resin. It will be understood that the adhesive strength reinforcing resin can be included in the insulating liquid to promote the bonding of the insulating liquid to the wires.

As appreciated by the present inventors, the viscosity of the liquid insulating material can be used to control the external shape of the formed separate insulating structures. In particular, as the viscosity is reduced, separate insulating structure of more uniform shape can be promoted and as the viscosity increases, the separate insulating structures may become larger. As further appreciated by the present inventors, the viscosity of the insulating liquid can be provided in a range of about several tens of centipoise (cps) to about several hundred cps. In some embodiments according to the invention, the viscosity can be in a range of about 10 cps to about 500 cps. In still other embodiments according to the invention, the viscosity can be in a range from about 20 cps to about 100 cps. It will be understood that the solvent described above as being part of the polymer can be used to control the viscosity. In particular, to promote the ranges described above, the solvent content can be limited to less than about 50% by weight of the polymer.

After formation of the separate insulating structures 145A and 145B as described above, the separate insulating structures can be subject to an induration process using a heat treatment, an ultraviolet radiation treatment, or a combination of heating and ultraviolet radiation. During this induration process, the solvent included in the polymer can be volatized. In some embodiments according to the invention, this volatization temperature of the solvent can be less than the induration temperature of the insulating material. For example, in some embodiments according to the invention, the induration temperature of an epoxy resin is about 70° C. whereas the induration temperature of a polyimide resin is about 200° C.

In still other embodiments according to the invention, separate induration processes can be provided where the first induration process is provided only to volatize the solvent whereas the second induration process is provided as part of the molding process to package the integrated circuit. In particular, as shown in FIG. 18, a molding material 150 is formed on the substrate so as to cover the wires and the separate insulating structures formed thereon. After completion of the molding process, the second induration process can be performed to thereby complete formation of the molding material as well as provide the induration temperature of the polyimide resin described above.

FIG. 19 is a table that provides exemplary parameters associated with an exemplary insulating material that can be used to form the separate insulating structures described herein. In particular, FIG. 19 shows parameters associated with a material available from Dow Corning Company referred to as Model ME-7700. During an exemplary process for formation of the separate insulating structures described herein, an Argon plasma treatment using 300 watts for about 300 seconds was provided using the Dow Corning Model ME-7700 in an amount of about 3+/−0.5 mg. sprayed at a height of about 4+/−1 mm above the substrate at a pressure of about 1 to about 20 MPa.

The above parameters can be used to form separate insulating structures on wires that vary in thickness from about 3 microns greater than the wire thickness to about less than 40 microns greater than the wire thickness on which the separate insulating structures are formed. Furthermore, the above process can form separate insulating structures with about 200 microns between immediately neighboring ones of the separate insulating structures formed on the same wire.

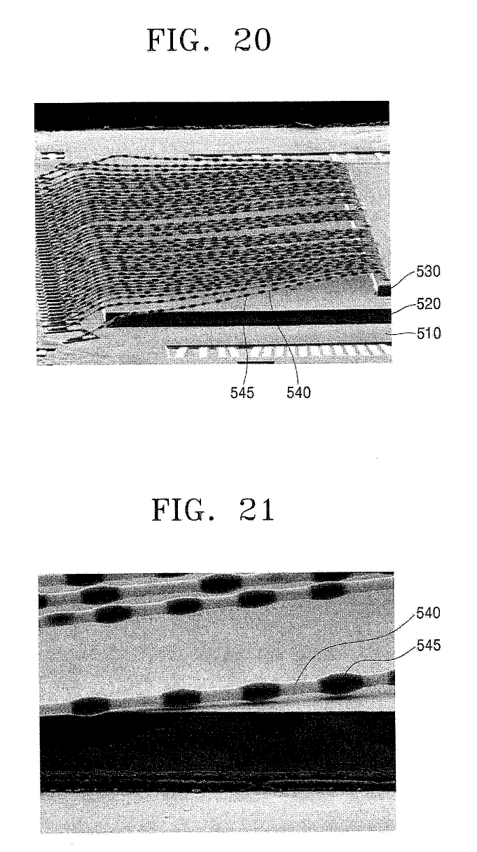

FIG. 20 is a photograph showing separate insulating structures 545 formed on wires electrically coupling a chip 530 to a substrate 510 having exposed portions 540 between ones of the separate insulating structures formed thereon. FIG. 21 shows an expanded view of the image shown in FIG. 20 further detailing the regular spacing of the separate insulating structures 545 formed on the wires and having the exposed portions that are free of the separate insulating structures 540 therebetween. As further shown in FIG. 21, the separate insulating structures 545 can function as stand-offs between the wire and the underlying substrate surface to avoid electrical shorting of the wire.

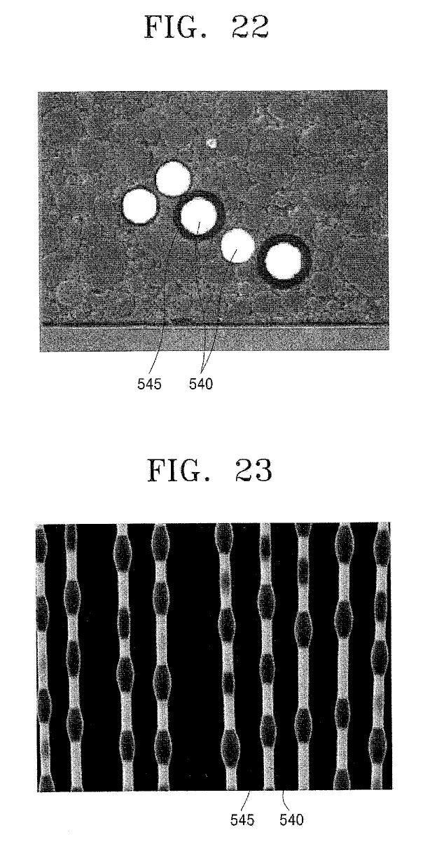

FIG. 22 shows a cross sectional photograph highlighting immediately neighboring wires 540 prevented from electrically shorting one another by the formation of the separate insulating structure 545 using an Argon plasma pretreatment process as described above in reference to FIGS. 16-18.

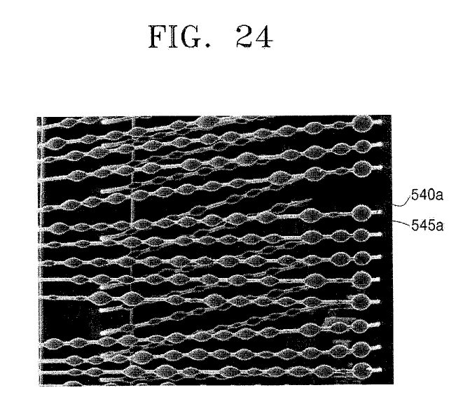

As shown in FIGS. 23 and 24, the external shapes of the separate insulating structures 545 can vary based on the viscosity of the insulating liquid used to form the separate insulating structures 545. In particular, as shown in FIG. 23, the separate insulating structures 545 can have an external shape which is oval-like. In contrast, the separate insulating structures 545A shown in FIG. 24 have a spherical external shape, which can be promoted by increased viscosity as described above.

As described herein, in some embodiments according to the invention, wires included in integrated circuit devices can have separate insulating structures formed thereon. The separate insulating structures on the wires can surround respective cross sectional portions of the wires, which can function as “stand-offs” to prevent immediately neighboring wires (or other neighboring components) from shorting together to thereby allow a reduction in defects associated with devices having reduced pitch between the wires (or other components). In some embodiments according to the invention, the separate insulating structures can have a substantially spherical external shape. In other embodiments according to the invention, the separate insulating structures can have a substantially oval external shape. In still further embodiments according to the invention, the spacing between the separate insulating structures can be substantially equal, and further, the exposed portions of the wire located between the separate insulating structures can also be substantially equal.

It will be apparent to those skilled in the art that various modifications and variations can be made in the invention. Thus, it is intended that the invention covers the modifications and variations of this invention provided they come within the scope of the appended claims and their equivalents.

What is claimed:

1. A semiconductor device comprising:
a substrate in the semiconductor device;
a chip on the substrate;
a wire electrically coupled to the chip; and
a plurality of separate insulator structures on the wire and surrounding respective cross-sectional portions of the wire.

2. A device according to claim 1 wherein portions of the wire located between immediately neighboring ones of the plurality of separate insulators are substantially free of the separate insulator structures.

3. A device according to claim 1 wherein the cross-sectional portions of the separate insulator structures comprise annular shapes.

4. A device according to claim 1 wherein the separate insulator structures comprise a shape including a diameter at a center of the shape that is greater than a diameter adjacent to an edge of the shape.

5. A device according to claim 1 wherein the separate insulator structures comprise an external shape being substantially spherical.

6. A device according to claim 1 wherein the separate insulator structures comprise an external shape being substantially oval.

7. A device according to claim 1 wherein the plurality of separate insulator structures are spaced along the wire at substantially equal intervals defining substantially equal exposed portions of the wire therebetween.

8. A device according to claim 1 wherein thicknesses at cross-sectional centers of the plurality of separate insulator structures are substantially equal.

9. A device according to claim 1 wherein the wire comprises a first wire, the device further comprising:
a second wire immediately neighboring the first wire, wherein each of the plurality of separate insulator structures is on and surrounds adjacent cross-sectional portions of the first and second wires.

10. A device according to claim 9 wherein the first and second wires comprise a group of wires and wherein a spacing between the wires included in the group is less than a spacing between the group and an immediately neighboring group of wires.

11. A device according to claim 1 wherein the wire comprises one wire included in a plurality of wires, the device further comprising:
respective pluralities of separate insulator structures on each of the wires in the plurality of wires, wherein surrounded cross-sectional portions of immediately neighboring wires are offset from one another.

12. A device according to claim 1 wherein the chip comprises a first chip, the device further comprising:
a second chip on the first chip in the device; and
a second wire electrically coupled to the second chip immediately above the first wire, wherein the first and second wires each include a respective plurality of separate insulator structures that surround cross-sectional portions of the first and second wires respectively.

13. A device according to claim 12 wherein the first and second wires are coupled between the first and second chips respectively and the substrate using a forward-bump or reverse-bump process.

14. An electronic system comprising:
a processor configured to coordinate operations of an electronic system;
a system interface, electrically coupled to the processor, configured to provide communications between the processor and external systems; and
a memory, electrically coupled to the processor, including at least one memory device comprising:
a chip on a substrate of the memory device;
a wire electrically coupled to the chip; and
a plurality of separate insulator structures on the wire and surrounding respective cross-sectional portions of the wire.

15. A memory card comprising:
a non-volatile memory controller configured to coordinate operations of the memory card; and
a memory, electrically coupled to the non-volatile memory controller, including a non-volatile memory comprising:
a chip on a substrate of the non-volatile memory;
a wire electrically coupled to the chip; and
a plurality of separate insulator structures on the wire and surrounding respective cross-sectional portions of the wire.

16. A method of insulating wires in a semiconductor device comprising:
forming a plurality of separate insulator structures on a wire to surround respective cross-sectional portions of the wire.

17. A method of insulating wires in a semiconductor device comprising:
pre-treating a wire coupled between a chip and a substrate to reduce surface tension between the wire and a material for deposition on the wire to provide a pretreated wire; and
forming a plurality of separate insulator structures comprising the material on the pretreated wire to surround respective cross-sectional portions of the wire.

18. A method according to claim 17 wherein pre-treating comprises applying a plasma treatment including Ar or N.

19. A method according to claim 17 wherein pre-treating comprises a wet process.

20. A method according to claim 17 wherein forming the plurality of separate insulator structures comprises applying an insulating liquid to the wire comprising:
a polymer including a base resin, an adhesive strength re-inforcing agent, an indurative catalyst, and a solvent.

21. A method according to claim 20 wherein the base resin comprises polymide resin, an acrylic resin, an epoxy resin, or a silicone resin.

22. A method according to claim 20 wherein the solvent comprises an organic solvent comprising less than about 50% by weight of the polymer.

23. A method according to claim 18 further comprising:
applying an induration treatment to the plurality of separate insulator structures at a temperature of about 200 degrees Centigrade.

24. A method according to claim 18 further comprising:
applying an induration treatment to the plurality of separate insulator structures using ultra-violet radiation.

25. A method according to claim 18 further comprising:
applying a first induration treatment to the plurality of separate insulator structures to volatize a solvent used to form the plurality of separate insulator structures; and then.
applying a second induration treatment to the plurality of separate insulator structures including an epoxy molding compound used to provide a molding material applied over the plurality of separate insulator structures.

26. A method according to claim 25 wherein applying the first induration treatment comprises applying the first induration treatment at a temperature of greater than about 70 degrees Centigrade.

27. A method according to claim 18 wherein forming the plurality of separate insulator structures comprises applying an insulating liquid to the wire comprising:
a polymer including a base resin, an adhesive strength re-enforcing agent, an indurative catalyst, and a solvent.

28. A method according to claim 25 wherein the base resin comprises polymide resin, an acrylic resin, an epoxy resin, or a silicone resin.
